(19) United States
(12) Patent Application Publication
(10) Pub. No.: US 2010/0171155 A1
(43) Pub. Date: Jul. 8, 2010

(54) Body-biased Silicon-On-Insulator Junction Field-Effect Transistor Having A Fully Depleted Body and Fabrication Method Therefor

(76) Inventor: Samar Kanti Saha, Milpitas, CA (US)

Correspondence Address: PERKINS COIE LLP, P.O. BOX 1208, SEATTLE, WA, 98111-1208, US

(21) Appl. No.: 12/350,926

(22) Filed: Jan. 8, 2009

(51) Int. Cl. H01L 29/78; H01L 21/337

(52) U.S. Cl. 257/256; 438/149; 438/186; 257/E29.314; 257/E21.446

(57) ABSTRACT

Silicon-on-insulator JFET having a body bias and a fully depleted body and fabrication methods therefore are disclosed. SOI JFETs offer leakage advantages over bulk silicon JFETs. However, some SOI JFETs have poor switching characteristics (e.g., high switch on time), and have poor leakage performance at high temperatures. The techniques herein introduced include a fully-depleted body SOI-JFET, with a non-zero bias applied to its body. In one example, the body region of the JFET can be fully depleted by tuning the thickness of the silicon containing layer of the SOI substrate. Additionally, the deep depletion can be induced by applying a non-zero bias to the body region, at a range of operating temperatures. Full body depletion and/or the application of body bias offers the benefits of suppressed leakage current at higher operating temperatures (e.g., between or above 25-115 C) and improved AC performance (e.g., faster switching time).

### TECHNICAL FIELD

This invention relates generally to semiconductor devices, and, in particular, to structures for field-effect transistors with a fully depleted body and methods for making such field-effect transistors.

### BACKGROUND

The continued downward size scaling of semiconductor devices (including, but not limited to, transistors) has enabled scaling of operating frequencies to continuously extend Moore's Law. Not only has the downward size scaling of device dimensions increased device performance, it has, also, allowed implementation of complex circuitry in smaller areas, facilitating compactness of portable electronics and other consumer electronics systems. In addition, it has allowed the fabrication of more complex circuits and devices on smaller substrates and at reduced cost.

Transistors with silicon-on-insulator (SOI) substrates have been known to provide several advantages during transistor operation. For example, SOI has enabled higher speed operation and lower power consumption by providing reduced capacitance and decreased substrate leakage currents. This has been beneficial in pushing SOI technology in applications involving high performance microprocessors and other advanced circuitry applications by lowering operating voltages, lowering power consumption, while providing higher temperature tolerance operation.

Furthermore, although some partially depleted body SOI JFETs offer leakage current advantages over bulk silicon JFETs, these partially depleted body SOI JFETs may also have poor switching characteristics.

The advantages of SOI wafers over the traditional bulk silicon substrates have further enabled device scaling. For example, since SOI based transistors are insulated, circuit size may be reduced due to increased circuit packing density. Furthermore, SOI technology does not require major modifications to process flows suitable for silicon wafers.

### SUMMARY

Body-biased silicon-on-insulator junction field-effect (SOI JFET) transistors having a fully depleted body and fabrication methods are described here. Silicon-on-insulator JFET having a body bias and a fully depleted body and fabrication methods therefor are disclosed.

Among the techniques herein introduced include a fully-depleted body SOI-JFET, with a non-zero bias applied to its body. In one non-limiting example, the body region of the JFET can be fully depleted by tuning the thickness of the silicon containing layer of the SOI substrate. Additionally, the strong depletion can be induced by applying a non-zero bias to the body region, at a range of operating temperatures. Full body depletion and/or the application of body bias offers the benefits of suppressed leakage current at higher operating temperatures (e.g., between or above 25-115 C) and improved AC performance (e.g., faster switching time).

Some non-limiting example embodiments are briefly described in this section.

In one non-limiting aspect, there is provided a junction field effect transistor (JFET), including: a silicon containing layer formed on a buried oxide layer; a channel region disposed in the silicon containing layer; a body region disposed between the channel region and the buried oxide layer; a gate region disposed within the channel region forming a gate-channel junction; a body contact electrically coupled to the body region; a depletion region comprising a gate-channel depletion region in the channel and gate regions and a channel-body depletion region in the body and channel regions; and a thickness of the silicon containing layer is less than or substantially equal to the depletion depth of the depletion region at substantially zero gate region bias and substantially zero body region bias.

In one non-limiting aspect, there is provided a junction field effect transistor, comprising: a silicon containing layer formed on a buried oxide layer; a channel region disposed in the silicon containing layer; a body region disposed between the channel region and the buried oxide layer; a body contact electrically coupled to the body region; and a depletion region comprising a channel-body depletion region in the body and channel region; wherein the channel-body depletion region in the body is substantially fully depleted when zero bias or near-zero bias is applied to the body contact.

In one non-limiting aspect, there is provided a method of fabricating a junction field-effect transistor (JFET) the method, comprising: forming a body region; forming a channel region of a first conductivity type in a thin silicon portion of a Silicon-On-Insulator (SOI) substrate; depositing a polysilicon layer on the channel region; patterning the polysilicon layer to define one or more of, a source region, a drain region, and a gate region; forming a gate contact; forming a gate region electrically coupled to the gate contact; and forming a body contact electrically coupled to the body region; wherein, a thickness of the thin silicon portion is determined based on one or more of a channel doping density and a body doping density.

In one non-limiting aspect, there is provided a method of improving performance of JFET operation, the method, comprising: applying non-zero body bias to a body contact of a JFET to reducing off-state current in a junction field-effect transistor (JFET).

In one non-limiting aspect, there is provided a junction field effect transistor of the type having a silicon containing layer formed on a buried oxide layer, a channel region disposed in the silicon containing layer, a body region disposed between the channel region and the buried oxide layer, a body contact electrically coupled to the body region, and wherein a depletion region comprising a gate-channel depletion region in the channel region and a channel-body depletion region in the body region, the junction field effect transistor is characterized in that: a thickness of the silicon containing layer is less than or substantially equal to a depletion depth of the depletion region at substantially zero gate bias and substantially zero body bias.

Other features of the present invention and embodiments thereof will be apparent from the accompanying drawings and from the detailed description.

### BRIEF DESCRIPTION OF THE DRAWINGS

FIG. 1A illustrates an example cross sectional view of an n-type silicon-on-insulator (SOI) junction field-effect transistor (n-JFET) having a fully depleted body region at approximately zero gate bias and approximately zero body bias and Shallow Trench Isolation (STI) region in the substrate, according to one embodiment.

FIG. 1B illustrates an example cross sectional view of a p-type silicon-on-insulator (SOI) junction field-effect transistor (p-JFET) having a fully depleted body (FDB) region at approximately zero gate bias and approximately zero body bias and Shallow Trench Isolation (STI) regions in the substrate, according to one embodiment.

FIG. 2A illustrates an example of a top view of a JFET showing the relative locations of the source, drain, gate, and body contacts, according to one embodiment.

FIG. 2B illustrates an example of 3D view of a JFET showing the relative locations of the body region and the body contact, according to one embodiment.

FIG. 2C illustrates an example of a cross sectional view along the width of an n-JFET showing the relative locations of the gate region, gate contact, body region, and body contact, according to one embodiment.

FIG. 3A illustrates an example cross sectional view of the depletion region distribution in an enhancement mode partially-depleted body SOI JFET having a partially depleted body region at approximately zero gate bias and approximately zero body bias.

FIG. 3B illustrates an example cross sectional view of the depletion region distribution in the enhancement mode partially-depleted body SOI JFET at a gate bias of approximately 0.5V.

FIG. 4A illustrates an example cross sectional view of the depletion region distribution in an enhancement mode fully-depleted body SOI JFET having a fully depleted body region at approximately zero gate bias and approximately zero body bias.

FIG. 4B illustrates an example cross sectional view of the depletion region distribution in the enhancement mode fully-depleted body SOI JFET at a gate bias of approximately 0.5V.

FIG. 5 illustrates an example plot showing the doping density distribution for both donors and acceptors along the depth of the active region of an enhancement mode fully-depleted body (FDB) SOI JFET, according to one embodiment.

FIG. 6 illustrates plots of simulated data for off-state leakage current (Ion) variations versus the applied body bias (or, also referred to as, back bias) for a partially-depleted body (PDB) SOI JFET and a fully-depleted body (FDB) SOI JFET at approximately 27 and 85 degrees Celsius.

FIG. 7A-FIG. 7B illustrates an example process flow for fabricating an enhancement mode SOI JFET having a fully depleted body region at approximately zero gate bias and approximately zero body bias.

### DETAILED DESCRIPTION

The following description and drawings are illustrative and are not to be construed as limiting. Numerous specific details are described to provide a thorough understanding of the invention and embodiments thereof. However, in certain instances, well-known or conventional details are not described in order to avoid obscuring the description. Features advantageously provided in some non-limiting embodiments are optional and not required in other embodiments.

Reference in this specification to “one embodiment” or “an embodiment” means that a particular feature, structure, or characteristic described in connection with the embodiment is included in at least one embodiment of the invention. The appearances of the phrase “in one embodiment” or “in one non-limiting embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way.

Consequently, alternative language and synonyms may be used for any one or more of the terms discussed herein, and no special significance should be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and is not intended to further limit the scope and meaning of the invention or of any example term. Likewise, the invention is not limited to various embodiments given in this specification.

Without intent to further limit the scope of the invention, examples of instruments, apparatus, methods and their related results according to the embodiments of the present invention are given below. Note that titles or subtitles may be used in the examples for convenience of a reader, which in no way should limit the scope of the invention. Unless otherwise defined, all technical and scientific terms used herein have the same meaning as commonly understood by one of ordinary skill in the art to which this invention pertains. In the case of conflict, the present document, including definitions will control.

The terminology used in the description presented below is intended to be interpreted in its broadest reasonable manner, even though it is being used in conjunction with a detailed description of certain specific examples of the invention. Certain terms may even be emphasized below; however, any terminology intended to be interpreted in any restricted manner will be overtly and specifically defined as such in this Detailed Description section.

Embodiments of the present invention include body-biased silicon-on-insulator (SOI) junction field effect transistors (JFET) having a fully depleted body region at zero gate bias and zero body bias and fabrication methods thereof. In general, embodiments of the techniques and advantages discussed herein are also applicable to approximately or substantially fully depleted bodies, including but not limited to 75-80% depletion, 80-85% depletion, 85-90% depletion, 90-95% depletion, more preferably 95-99%, or yet more preferably over 98% depletion.

Although embodiments of the present invention are described with example reference to silicon-based junction field effect transistors (JFET), the application of the novel aspect of the invention is not limited as such. Applications of the techniques discussed herein to other types of devices of additional or same materials systems (e.g., Si, Ge, GaAs, other III-V systems, and the like) are contemplated and are considered to be within the scope of this invention, including but not limited to, metal-semiconductor field effect transistors (MESFETs), Ge/Si FETs, and/or any other semiconductor device whereby a depleted channel is modulated by a bias applied to a terminal.

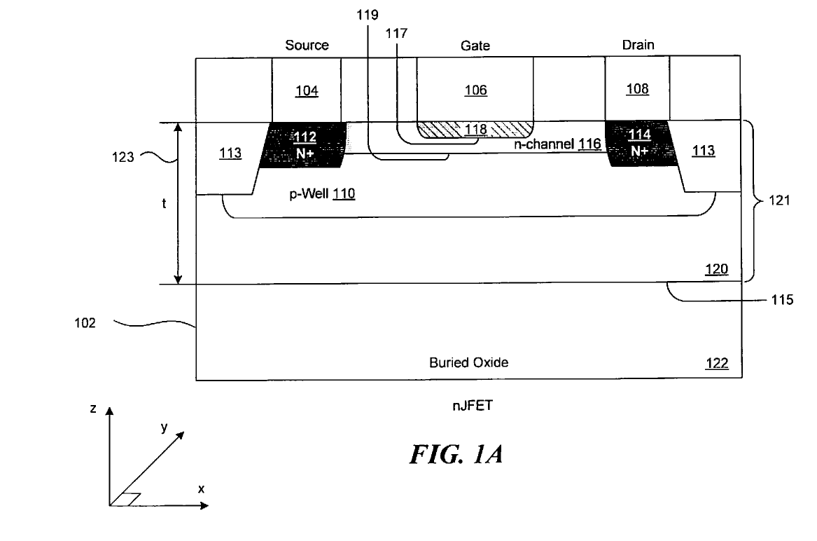

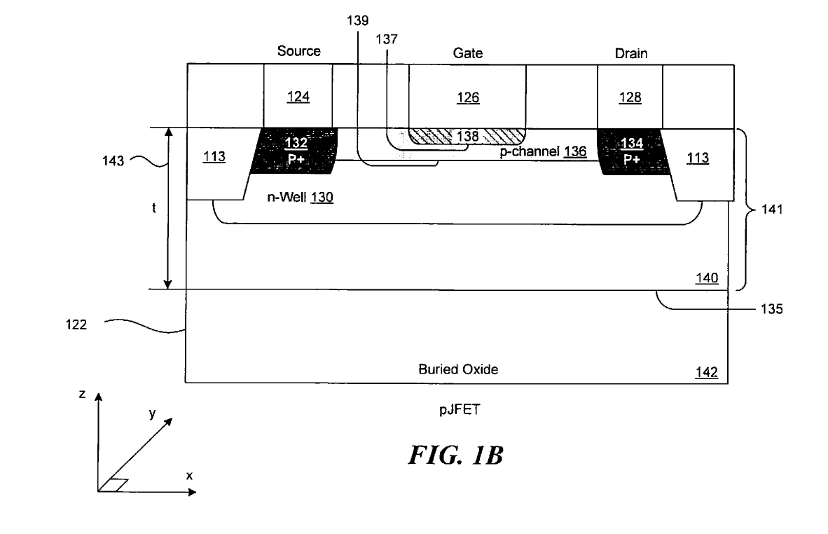

FIG. 1A illustrates an example of a cross sectional view of an n-type junction field-effect transistor (n-JFET) 102 with a fully-depleted body in off-state, according to one embodiment.

The n-JFET 102 may be fabricated from any known and/or convenient methods. The n-JFET 102 includes polysilicon contacts including, a source terminal 104, a gate terminal 106, and a drain terminal 108. In addition, the terminals (e.g., source terminal/contact, gate terminal/contact, and/or drain terminal/contact) may comprise metallic material rather than polysilicon. Silicide (such as for example, self-aligned silicide) may optionally additionally be formed on the source, drain, and gate contacts. Shallow Trench Isolation (STI) region 113 may also be provided within the substrate.

Further, the gaps between source, gate, and drain contacts may optionally be filled with dielectric material to passivate or protect the surface of the transistor from contamination. The material could be standard or low-k dielectric which also has the benefit of improving interconnection capacitance. In other instances, silicon dioxide or other dioxides may also be used to fill the gaps between the source, gate and drain contacts and to further improve interconnection capacitance.

The n-JFET 102 further optionally includes link regions (e.g., n-link region, not illustrated) extending along the channel from the source region 112 and the drain region 114 towards the gate region, respectively. The link regions of the n-JFET 102 are generally doped with n-type impurities so as to provide additional charge carriers during on-state of the n-JFET 102. The link regions provide carriers in addition to the carriers supplied via the source region 112, drain region 114, and the channel region 116.

The n-JFET 102 further includes a p-type doped region 110, referred to as the p-well, in which the channel region 116 (e.g., n-channel), source region 112, and the drain region 114 are formed. The p-well 110 constitutes the body region of n-JEFT 102.

In one embodiment, the n-JFET 102 is disposed on an SOI substrate having a silicon containing layer 121 formed on a buried oxide layer 122. The silicon containing layer 121 mostly includes silicon (e.g., crystalline silicon) with or without impurities. The buried oxide layer 122 is approximately although not limited to about 150 nm. The n-JFET can also include a silicon region 120. The region 120 constitutes the silicon region of the SOI substrate where, p-type doped well region 110 is formed for n-JFET 102. The gate region 118 (e.g., p-type doped for n-JFET 102) is disposed within the channel region 116. A gate-channel junction 117 is formed between the channel region 116 and the gate region 118. When the region 120 is formed of a p-type material, the p-body of n-JFET extends down to the interface 115 between the region 120 and the buried oxide 122 of the SOI as illustrated. Alternatively, when the region 120 is formed of an n-type body material, the p-well 110 is made deep so that the p-body of n-JFET extends down to the interface 115 between the region 120 and the buried oxide 122 of the SOI.

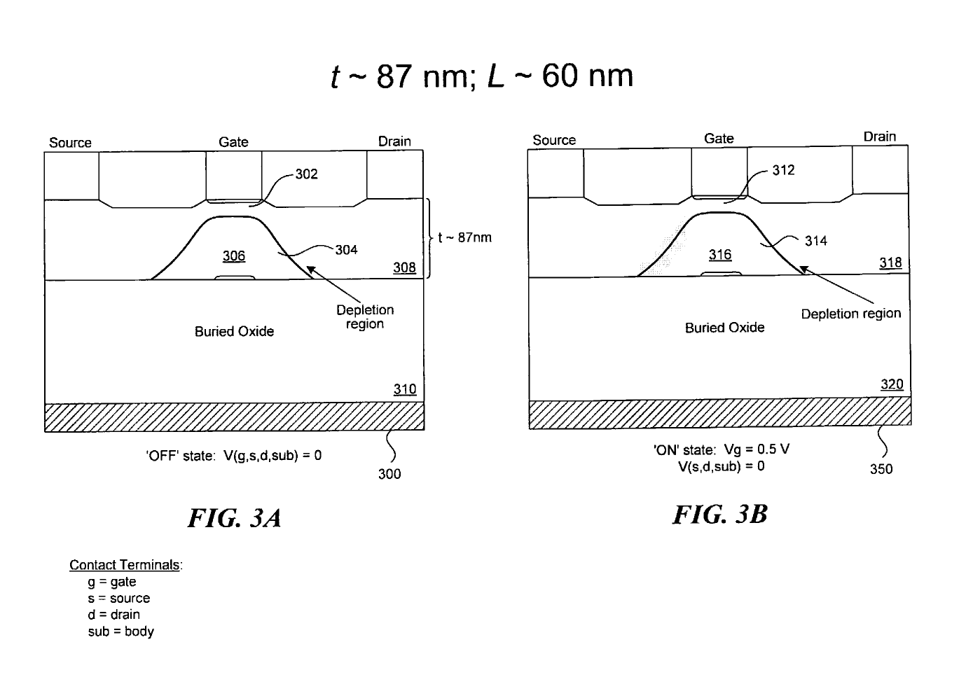

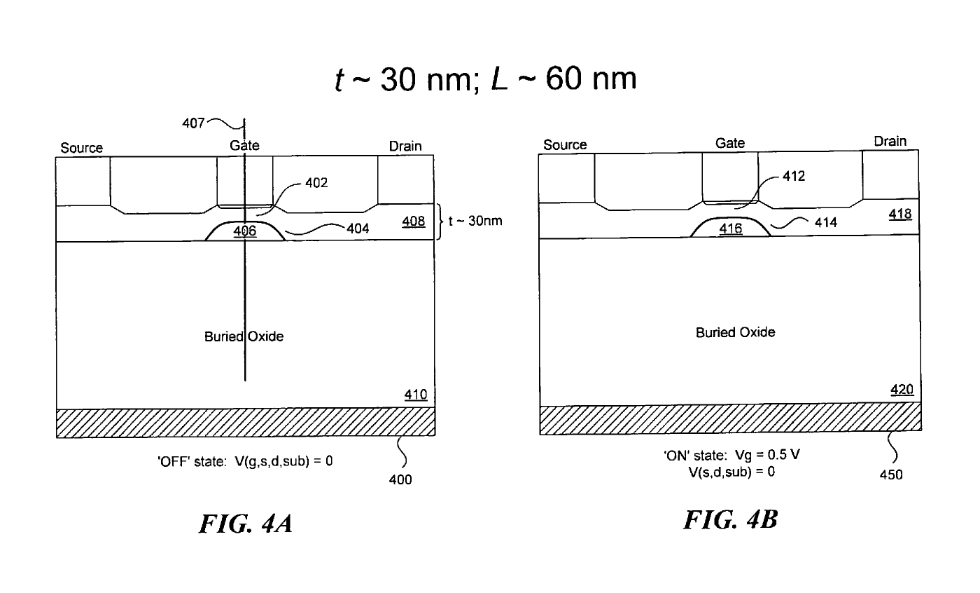

In one embodiment, for an n-JFET 102 in the off-state, the depletion region includes a gate-channel depletion region in the channel region and gate region, and a channel-body depletion region in the body region and the channel region. The gate-channel depletion region and the channel body depletion region are illustrated with further references to the examples of FIG. 3 and FIG. 4. The depth of the depletion region (e.g., including the gate-channel depletion regions and the channel-body depletion regions) can be modulated by a gate bias applied to the gate contact 106. According to non-limiting embodiments of the present invention, the depletion region disposed in the channel and body is fully depleted at zero gate bias.

In particular, the thickness of the silicon containing layer 121 has a thickness ‘t’ 123 that is less than or approximately equal to the depletion depth of the depletion region at zero gate bias. For example, the thickness ‘t’ 123 does not exceed the combination (e.g., sum) of the depths of the gate-channel depletion region into the channel and the channel-body depletion region into the body under zero gate bias conditions. In general, the thickness ‘t’ 123 of the silicon containing layer 121 in the SOI n-JFET 102 can be chosen as a function of channel doping concentration to fully deplete or substantially/approximately fully deplete the gate-channel and channel-body depletion regions.

In general, embodiments of the techniques and advantages discussed herein are also applicable to approximately or substantially fully depleted gate-channel depletion region in the channel and body channel depletion region in the body, including but not limited to 75-80% depletion, 80-85% depletion, 85-90% depletion, 90-95% depletion, more preferably 95-99%, or yet more preferably over 98% depletion. Therefore, the thickness ‘t’ 123 may in some instances slightly exceed the depletion depth at zero gate bias and achieve, according to some embodiments, 75-98% depletion.

Thus, in one embodiment, the thickness ‘t’ 123 of the silicon containing layer 121 is typically although not necessarily within the range of 30 to 40 nm and the channel doping concentration is typically although not necessarily within the range of 5e¹⁸ to 5e¹⁹ cm⁻³. In one embodiment, the thickness ‘t’ 123 of the silicon containing layer 121 may be within the range of 20 to 50 nm. For example, the thickness ‘t’ 123 can be approximately 15, 20, 25, 30, 32.5, 35, 37.5, 40, 45, 50 nm or any other suitable values. Correspondingly, the channel doping concentration can be approximately, 1e¹⁷, 2e¹⁷, 5e¹⁷, 1e¹⁸, 2e¹⁸, 5e¹⁸, 1e¹⁹, 2e¹⁹, 5e¹⁹, 1e²⁰ cm⁻³, or any other suitable doping densities.

Additionally, the thickness ‘t’ 123 of the silicon containing layer 121 can be chosen as a function of body doping concentration such that the channel-body depletion region inside the body is approximately fully depleted with zero bias or approximately zero bias applied to the gate contact. Therefore, the body doping concentration is typically although not necessarily within a range of 1e¹⁸ to 1e¹⁹ cm⁻³. For example, the body doping concentration can be approximately 1e¹⁷, 2e¹⁷, 5e¹⁷, 5e¹⁸, 2e¹⁸, 5e¹⁸, 1e¹⁹, 2e¹⁹, 5e¹⁹, 1e²⁰ cm⁻³, or any other suitable doping densities.

In a fully-depleted body (FDB) or approximately fully-depleted body SOI JFET, the silicon containing layer 121 is thinner than or approximately equal to the depth of the total depletion region in the channel and body. In the FDB-SOI JFET, the depletion region in the body is pinned at the interface 115 between the body region 120 and the buried oxide layer 122. In other words, the depletion region extends through out the channel region 116 through the body region 120 and terminates at the interface 115.

The fully-depleted body 120 of the n-JFET 102 results in an induced body bias which improves the on-off characteristics (e.g., improved AC performance and enhanced switching speed) of the n-JFET, Body bias can be induced due to an applied gate bias that induces charge on a floating body thus forward biasing the body-channel junction and pulling down the channel-body junction depletion in the channel at the bottom of the channel. The induced body bias therefore reduces the switching time by allowing the device to switch on faster. On-current is also increased.

In other words, in the on-state, the body bias induced by the fully-depleted body enables the gate-channel depletion region and/or the channel-body depletion region to un-deplete or to have carriers restored to the region faster to open up the channel 116 thus enabling current flow, in both single gate and double gate configurations. In the off-state, since the body-depletion is pinned at 115, most of the depletion modulation is in the channel thus placing the channel in strong depletion and decreasing the off state leakage current. In general, the switching time can be determined by sub-threshold slope (S-factor) of JFET devices. In one embodiment, the S-factor for the fully-depleted body SOI JFET is reduced from approximately 80 mV/decade to substantially less than or equal to 70 mV/decade.

In one embodiment, n-JFET 102 includes a body contact that is electrically coupled to the body region. The body contact can be biased to modulate the depletion region (e.g., the channel-body depletion). For example, in the off-state, the body contact can be biased to further reverse bias the channel-body P-N junction resulting in deeper depletion in the channel region.

The additional reverse bias in the off-state further depletes mobile carriers (e.g., minority or majority carriers, holes and/or electrons) from the channel region thus suppressing carrier flow that result in lower off-state leakage by reducing the carrier spill over the Debye length at the depletion edge. The Debye length is the portion of material exceeding beyond the depletion edge where the carriers are mobile. These mobile carriers generally contribute to off-state leakage current. Thus, by additional body bias, the carrier-spill over region is eliminated by deep overlap of depletion regions from the body into the channel and from the gate into the channel and subsequently, the off-state leakage current can be suppressed. The off-state current may arise from carrier generation and recombination in the depletion region.

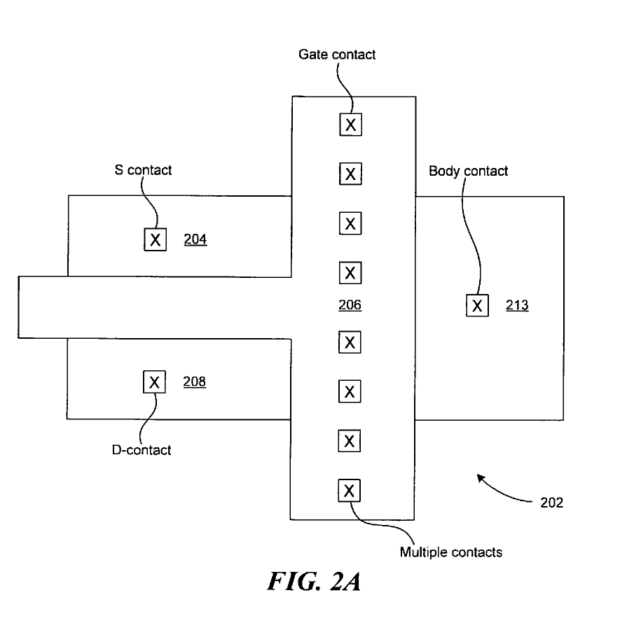

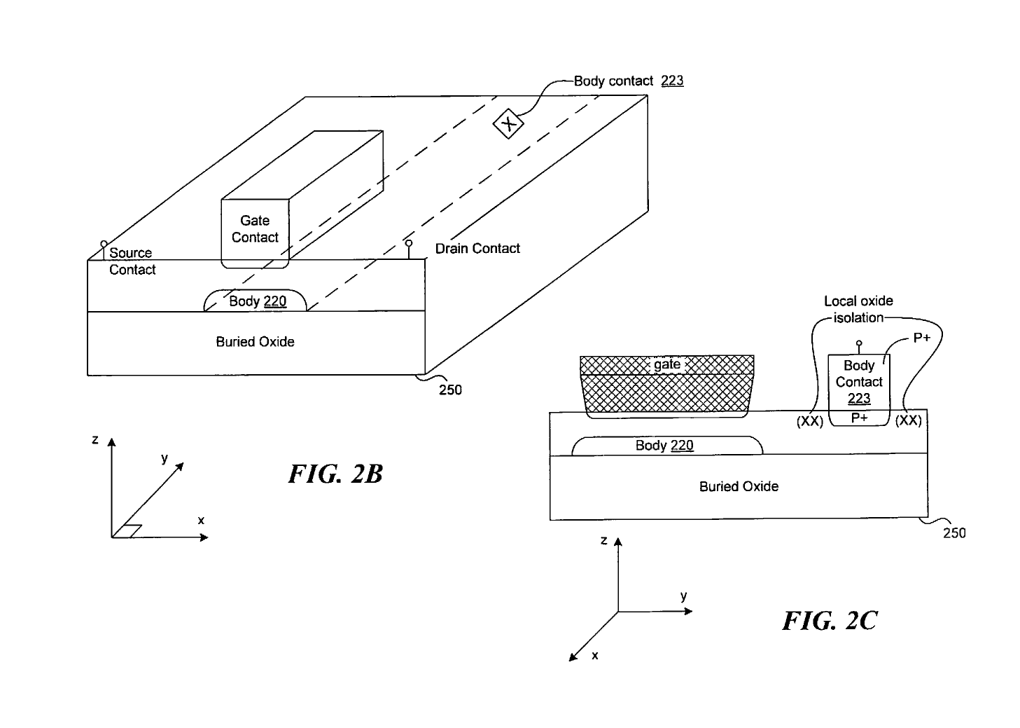

Although the body contact is not visible in the example of FIG. 1A, the body contact is shown with further reference to the examples of FIG. 2A-C. The body contact can be kept floating or tied to ground. In some embodiment, the body contact bias is adjusted based on the operating temperature. For example, the body bias voltage is generally a value between approximately −Vdd/2 volts and −Vdd volts, where Vdd is the value of the positive supply voltage applied to the n-JFET

The body contact bias can be tuned to suppress the off-state leakage to a predetermined level at any given operating temperature (e.g., elevated operating temperatures above room temperature such as but not limited to, temperatures between 25-150 C). Therefore, body-biased fully depleted body JFETs (e.g., the n-JFET 102) generally can be tuned to have lower off-state leakage compared to bulk JFETs, SOI JFETs, partially depleted body JFETs, or non-body biased fully depleted body JFETs.

In most instances, the off-state leakage current can be reduced by at least ⅓ to ½ compared to bulk silicon JFET, SOI JFET, or a partially depleted JFET. In some instances, the off-state current can be reduced by a factor of 10 with or without the application of a body bias. In one embodiment, the off-state leakage current is between approximately 100 pA/um (100×10⁻¹² A/um) and 10 nA/um (10×10⁻⁹ A/um).

Fully-depleted n-JFETs such as a fully-depleted body n-JFET 102 enables power savings due to lower voltage operations. In addition, low chip stand-by current (by virtue of having a lower off-state current) results in a reduction of power-consumption, in some instances, exceeding 30% compared to conventional JFETs. In the off-state, the leakage current of the fully-depleted body JFET 102 is lower compared to the conventional bulk and SOI JFETs since the channel-body depletion region in the body is pinned at the interface 115 between the body region 120 and the buried oxide 122, the channel region enters into strong depletion thus effectively depleting carriers (e.g., including thermally generated carriers) from the channel region 116.

In general, the off-state current of a fully depleted body JFET (e.g., the fully depleted body n-JFET 102) is reduced as compared to the off-state current of a bulk silicon JFET, SOI JFET, and/or a partially-depleted (body) SOI JFET. For example, the off-state current of a fully-depleted body JFET may be between approximately 100 pA/um and 10 nA/um.

Furthermore, the capacitance of a fully-depleted body JFET (e.g., n-JFET 102) is significantly reduced, particularly, due to the reduction/elimination of the source/drain P-N junction parasitic capacitance. In many instances, the capacitance of the fully-depleted JFET is reduced by approximately 20-50% compared to bulk silicon JFET, SOI JFET, and/or a partially-depleted body SOI JFET.

Methods for operating a JFET (n-JFET and/or p-JFET) and the related principles of operations (e.g., in the enhancement mode and the depletion mode) are known to those skilled in the art and are not further described here. In one embodiment, the n-JFET operates in the enhancement mode, or otherwise referred to as the normally-off mode. The innovative semiconductor devices and structures operating in these modes have enhanced operating characteristics and performance over conventional devices and structures, including by way of example, but not limitation, improved electrostatics (reduced parasitic capacitance), reduced off-state leakage current, enhanced switching time, improved power consumption, and other implications thereof.

FIG. 1B illustrates an example of a cross sectional view of a p-type junction field-effect transistor (p-JFET) 122 with a fully-depleted body in off-state, according to one embodiment. A Shallow Trench Isolation (STI) region may also be provided.

The p-JFET 122 may be fabricated from any known and/or convenient methods. The p-JFET 122 includes polysilicon contacts including, a source terminal 124, a gate terminal 126, and a drain terminal 128. In addition, the terminals (e.g., source terminal/contact, gate terminal/contact, and/or drain terminal/contact) may comprise metallic material rather than polysilicon. Silicide (such as for example, self-aligned silicide) may optionally additionally be formed on the source, drain, and gate contacts.

Further, the gaps between source, gate, and drain contacts may optionally be filled with dielectric material to passivate or protect the surface of the transistor from contamination. The material could be standard or low-k dielectric which also has the benefit of improving interconnection capacitance. In other instances, silicon dioxide or other dioxides may also be used to fill the gaps between the source, gate and drain contacts and to further improve interconnection capacitance.

The p-JFET 122 further optionally includes link regions (e.g., p-link region, not illustrated) extending from the source region 132 and the drain region 134 towards the gate region, respectively. The link regions of the p-JFET 122 are generally doped with p-type impurities so as to provide additional charge carries during on-state of the p-JFET 122. The link regions provide carriers in addition to that supplied via the source region 132, drain region 134, and the channel region 136.

The p-JFET 122 further includes an n-type doped region 130 referred to as the n-well, in which the channel region 136 (e.g., p-channel), source region 132, and the drain region 134 are formed. The n-well 130 constitutes the body region of the p-JFET 122.

In one embodiment, the p-JFET 122 is disposed on an SOI substrate having a silicon containing layer 141 formed on a buried oxide layer 142. The silicon containing layer 141 mostly includes silicon (e.g., crystalline silicon) with or without impurities. The buried oxide layer is approximately although not limited to 150 nm. The p-JFET may also include a Silicon-On-Insulator (SOI) substrate comprising a silicon layer 140 and a buried oxide layer 142. The region 140 constitutes the silicon region of the SOI substrate where, n-type doped well region 130 is formed for p-JFET 122. The gate region 138 (e.g., n-type doped for p-JFET 122) is disposed within the channel region 136. A gate-channel junction 137 is formed between the channel region 136 and the gate region 138. When the region 140 is formed of a p-type material, the n-well 130 is made deep so that the n-body of p-JFET extends down to the interface 135 between the region 140 and the buried oxide 142 of the SOI as illustrated. Alternatively, when the region 140 is formed of an n-type material, the n-body of p-JFET extends down to the interface 135 between the region 140 and the buried oxide 142 of the SOI.

In one embodiment, for a p-JFET 122 in the off-state, the depletion region includes a gate-channel depletion region in the channel region and a channel-body depletion region in the body region and the channel region. The gate-channel depletion region and the channel body depletion region are illustrated with further references to the examples of FIG. 3 and FIG. 4. The depth of the depletion region (e.g., including the gate-channel depletion and the channel-body depletion) can be modulated by a gate bias applied to the gate contact 126. According to embodiments of the present invention, the depletion region is fully depleted at zero gate bias.

In particular, the thickness of the silicon containing layer 141 has a thickness ‘t’ 143 that is less than or approximately equal to the depletion depth of the depletion region at zero gate bias. For example, the thickness ‘t’ 143 does not exceed the combination (e.g., sum) of the depths of the gate-channel depletion region inside the channel, and the channel-body depletion region inside the body under zero gate bias conditions. In general, the thickness ‘t’ 143 of the silicon containing layer 141 in the SOI p-JFET 142 can be chosen as a function of channel doping concentration to fully deplete the gate-channel and channel-body depletion regions.

Thus, in one embodiment, the thickness ‘t’ 143 of the silicon containing layer 141 is typically although not necessarily within the range of 30 to 40 nm and the channel doping concentration is typically although not necessarily within the range of 5e¹⁸ to 5e¹⁹ cm⁻³. In one embodiment, the thickness ‘t’ 123 of the silicon containing layer 121 may be within the range of 20 to 50 nm. For example, the thickness ‘t’ 143 can be approximately 15, 20, 25, 30, 32.5, 35, 37.5, 40, 45, 50 nm or any other suitable values. Correspondingly, the channel doping concentration can be approximately, 1e¹⁷, 2e¹⁷, 5e¹⁷, 1e¹⁸, 2e¹⁸, 5e¹⁸, 1e¹⁹, 2e¹⁹, 5e¹⁹, 1e²⁰ cm⁻³, or any other suitable doping densities.

Additionally, the thickness ‘t’ 143 of the silicon containing layer 141 can be chosen as a function of body doping concentration such that the channel-body depletion region inside the body is approximately fully depleted with zero bias or approximately zero bias applied to the gate contact. Therefore, the body doping concentration is typically although not necessarily within a range of 1e¹⁸ to 1e¹⁹ cm⁻³. For example, the body doping concentration can be approximately 1e¹⁷, 2e¹⁷, 5e¹⁷, 1e¹⁸, 2e¹⁸, 5e¹⁸, 1e¹⁹, 2e¹⁹, 5e¹⁹, 1e²⁰ cm⁻³, or any other suitable doping densities.

In a fully-depleted body (FDB) or approximately fully-depleted body SOI JFET, the silicon containing layer 141 is thinner than or approximately equal to the depth of the total depletion region. In the FDB-SOI JFET, the depletion region is pinned at the interface 135 between the region 140 and the buried oxide layer 142. In other words, the depletion region extends through out the channel region 136 through the body region 140 and terminates at the interface 135.

The fully-depleted body of the p-JFET 122 results in an induced body bias which improves the on-off characteristics (e.g., improved AC performance and enhanced switching speed) of the p-JFET. The induced body bias reduces the switching time by allowing the device to switch on faster. In other words, the body bias induced by the fully-depleted body enables the gate-channel depletion region and/or the channel-body depletion region to un-deplete or to have carriers restored to the region faster to open up the channel 136 thus enabling current flow, in both single gate and double gate configurations.

In one embodiment, p-JFET 122 includes a body contact that is electrically coupled to the body region. The body contact can be biased to modulate the depletion region (e.g., the channel-body depletion). For example, in the off-state, the body contact can be biased to further reverse bias the channel-body P-N junction resulting in deeper depletion in the channel region.

The additional reverse bias in the off-state further depletes mobile carriers (e.g., minority or majority carriers) from the channel region thus suppressing carrier flow that result in off-state leakage by reducing the carrier spill over the Debye length at the depletion edge.

Although the body contact is not visible in the example of FIG. 1B, the body contact is shown with further reference to the examples of FIG. 2A-2C. The body contact can be kept floating or tied to ground. In some embodiment, the body contact bias is adjusted based on the operating temperature. For example, the body contact bias can be tuned to suppress the off-state leakage current to a predetermined level at any given operating temperature. Therefore, body-based fully depleted body JEFTS (e.g., the p-JFET 122) generally can be tuned to have lower off-state leakage compared to bulk JFETs, SOI JFETs, partially depleted body JFETS, or non-body biased fully depleted body JFETS.

Fully-depleted p-JFETs such as a fully-depleted body p-JFET 122 enables power savings due to lower voltage operations. In addition, low chip stand-by current (by virtue of having a lower off-state current) results in a reduction of power-consumption, in some instances, exceeding 30% compared to the conventional JFETs. In the off-state, the leakage current of the fully-depleted body JFET 122 is lower compared to the conventional bulk and SOI JFETs since the channel-body depletion region extends through the body to the interface 135 between the region 140 and the buried oxide 142 thus effectively depleting carriers (e.g., thermally generated carriers) from the channel region 136.

In general, the off-state current of a fully depleted body JFET (e.g., the fully depleted body p-JFET 122) is reduced as compared to the off-state current of a bulk silicon JFET, SOI JFET, and/or a partially-depleted (body) SOI JFET. For example, magnitude of the off-state current of a fully-depleted body JFET may typically be between approximately 100 pA/um and 10 nA/um.

Furthermore, the capacitance of a fully-depleted body JFET (e.g., p-JFET 122) is significantly reduced, particularly, due to the reduction/elimination of the source/drain P-N junction parasitic capacitance. In many instances, the capacitance of the fully-depleted JFET is reduced by approximately 20-50% compared to bulk silicon JFET, SOI JFET, and/or a partially-depleted (body) SOI JFET.

In one non-limiting embodiment, the p-JFET operates in the enhancement mode, or otherwise referred to as the normally-off mode.

FIG. 2A illustrates an example of a top view of a JFET 202 showing the relative locations of the source contact 204, drain contact 208, gate contact 206, and body contact 213, according to one embodiment.

The body contact 213 is doped with the same polarity as the body region. In an n-JFET (e.g., n-JFET 102 of FIG. 1A), the body contact 213 and the body region are doped p-type whereas in a p-JFET (e.g., p-JFET 122 of FIG. 1B) are doped n-type. The body contact 213 is electrically coupled to the body region and can be biased to modulate the depletion depth of a channel-body depletion region. In some instances, the body contact 213 is used to suppress off-state leakage current by strongly depleting the channel depletion region mobile carriers, as described with further reference to the examples of FIG. 1A-1B. Although the gate contact 206 is illustrated as having a ‘T’-shaped structure, contacts of other shapes and configurations are contemplated, including but not limited to ‘L’-shaped gate structures, and can be implemented as suitable or as necessary and are considered to be within the novel art of this innovation.

FIG. 2B illustrates an example of 3D view of a JFET 250 showing the relative locations of the body region 220 and the body contact 223, according to one embodiment.

FIG. 2C illustrates an example of a cross sectional view along the width of the JFET 250 showing the relative locations of the gate region, gate contact, body region 220, and body contact 223, according to one embodiment. The body contact and the body region are doped of the opposite impurity type as the channel region. For example, for an n-JFET, the body contact and the body regions are doped p-type.

FIG. 3A illustrates an example cross sectional view of the depletion region distribution simulated for an enhancement mode partially-depleted body SOI JFET 300 having a partially depleted body region at zero gate bias and zero body bias.

In this cross sectional view, the source, gate, drain regions, silicon containing layer 308, and buried oxide layer 310 are depicted. The spatial distribution of the depletion region in the off-state for the SOI JFET 300 with a non-fully depleted body (e.g., may also be referred to as a partially-depleted body (PDB) SOI JFET) can be visualized in a cross sectional view of the simulated electrostatics in the device.

As shown, in the off-state (e.g., when zero bias or substantially zero bias is applied to the source, drain, and gate), the gate-channel depletion region 302 inside the channel is fully depleted whereas the channel-body depletion region 304 inside the body is not. In other words, in the off-state, the channel-body depletion region 304 only extends partially through the body region 306 and does not reach the edge of the buried oxide layer 310. Note that approximately zero bias refers generally to plus/minus 50 mV.

FIG. 3B illustrates an example cross sectional view of the depletion region distribution simulated for the enhancement mode partially-depleted body SOI JFET 350 at a gate bias of 0.5V.

In this cross sectional view, the source, gate, drain regions, silicon containing layer 318, and buried oxide layer 320 are depicted. The spatial distribution of the depletion region in the on-state for the SOI JFET 350 with a non-fully depleted body (e.g., may also be referred to as a partially-depleted body (PDB) SOI JFET) can be visualized in a cross sectional view of the simulated electrostatics in the device. As shown, in the on-state (or with 0.5V gate bias and zero drain/source bias), the gate-channel depletion region 312 opens up and the channel-body depletion region 314 shrinks as compared to the partially-depleted body SOI JFET in the off-state.

FIG. 4A illustrates an example cross sectional view of the depletion region distribution simulated for an enhancement mode fully-depleted body SOI JFET 400 having a fully depleted body region at zero gate bias and zero body bias.

In this cross sectional view, the source, gate, drain regions, silicon containing layer 408, and buried oxide layer 410 are depicted. The spatial distribution of the depletion region in the off-state for one embodiment of the SOI JFET 400 with a fully depleted body (e.g., FDB SOI JFET) can be visualized in a cross sectional view of the simulated electrostatics in the device. As shown, in the off-state (or when zero bias is applied to the source, drain, and gate), the gate-channel depletion region 402 has fully depleted the channel and the channel-body depletion region 404, also, has fully depleted the body. In other words, the channel-body depletion region 404 extends throughout the body region 406 to the edge of the buried oxide layer 410.

The thickness of the silicon containing layer 408 of the fully-depleted body SOI JFET is thinner than the thickness of the silicon containing layer 308 of the partially-depleted body SOI JFET 300 in the example of FIG. 3A. In accordance with one embodiment, the thickness “t” of the silicon containing layer 408 is tuned to the channel and body doping densities such that the channel-body depletion region 404 is fully-depleted in the off-state. Thus, in one embodiment, a fully-depleted body SOI JFET can generally be fabricated from thinning the silicon containing layer of a bulk SOI device or an otherwise partially-depleted body SOI JFET. In the fully-depleted body SOI JFET, the depletion is pinned at the interface between the body and the buried oxide thus the depletion predominantly modulates the channel depletion thus improving switch on time.

FIG. 4B illustrates an example cross sectional view of the depletion region distribution simulated for the enhancement mode fully-depleted body SOI JFET 450 at a gate bias of 0.5V.

In this cross sectional view, the source, gate, drain regions, silicon containing layer 418, and buried oxide layer 420 are depicted. The spatial distribution of the depletion region in the on-state for one embodiment of the SOI JFET 450 with a fully depleted body (e.g., FDB SOI JFET) can be visualized in a cross sectional view of the simulated electrostatics in the device. As shown, in the on-state (or with 0.5V gate bias and zero drain/source bias), the gate-channel depletion region 412 shrinks such that the channel opens up and the channel-body depletion region 414 in the body 416 remains fully depleted. Since the body region is very thin and is less than the depletion width, at the on-state or forward bias, the depletion region is modulated mostly in the channel region. In other words, the channel-body depletion region 414 extends throughout the body region 416 to the edge of the buried oxide layer 420 when the channel opens up in the on-state, according to one embodiment. It may also be noted that the thickness of the silicon containing layer 418 of the fully-depleted body SOI JFET is thinner than the thickness of the silicon containing layer of the partially-depleted body SOI JFET in the earlier example.

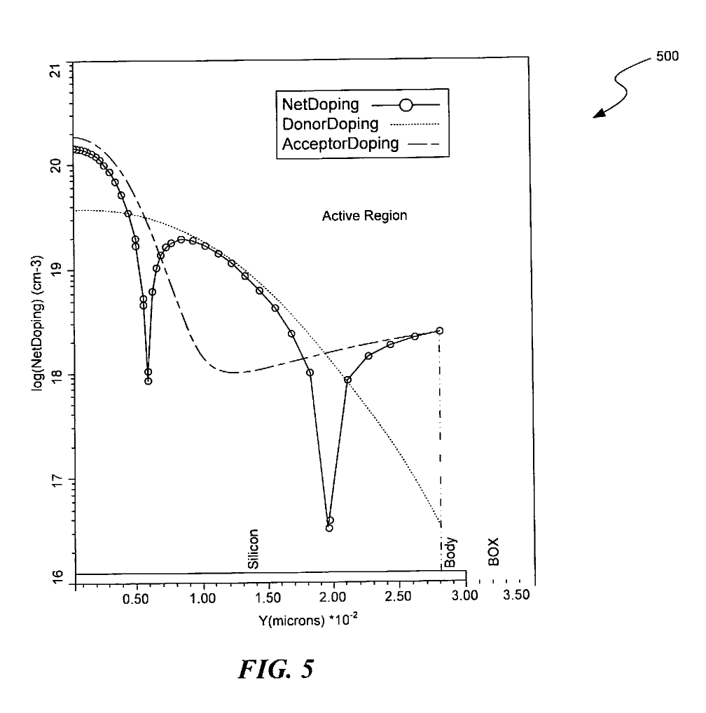

FIG. 5 illustrates an example graphical plot 500 on a partial logarithmic scale of Net, Donar, and Acceptor Doping versus depth of the SOI n-JFET showing the doping density distribution for both donors and acceptors along the depth of the active region of an enhancement mode fully-depleted body (FDB) SOI n-JFET, according to one embodiment. For a p-JFET, the dopant polarities will be opposite and acceptor doping and donor doping are interchanged in the figure.

The spatial distribution of doping densities across the depth of the n-JFET is illustrated on a logarithmic scale. The donor doping, acceptor doping, and net doping profiles are plotted along the depth of a n-JFET through the silicon containing portion including the body region and the buried oxide layer. These profiles may be seen in the section shown by line 407 or in FIG. 4A. In general, a uniform doping profile is ideal throughout the silicon region. The lower doping level in the body region facilitates full body depletion, thus further reducing capacitance.

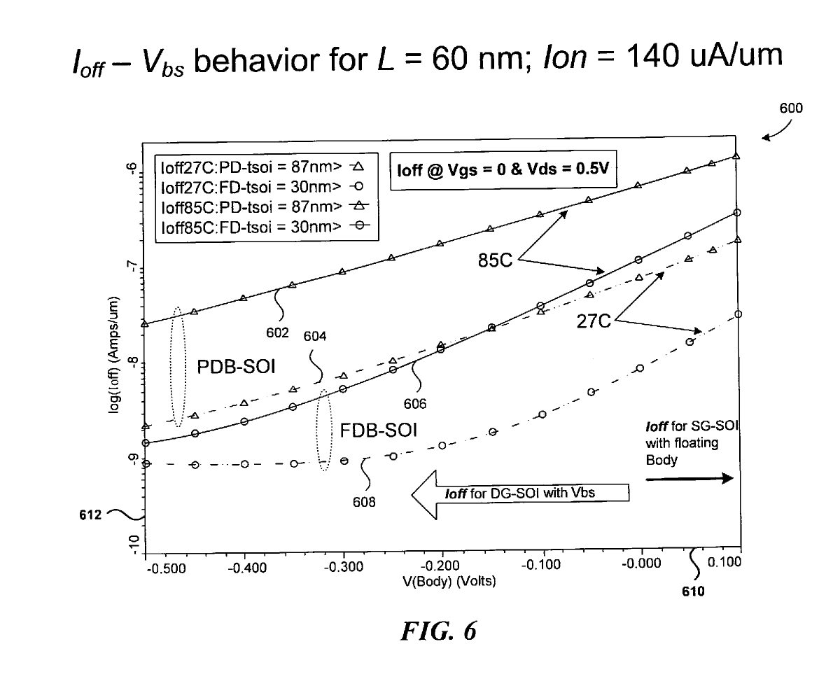

FIG. 6 illustrates plots 600 of simulated data for off-state leakage current (I_{off}) variations versus the applied body bias (or, also referred to as, back bias) for a partially-depleted body (PDB) SOI n-JFET and a fully-depleted body (FDB) SOI n-JFET at 27 and 85 degrees Celsius, respectively.

Data are obtained from simulation of FDB SOI n-JFET and PDB SOI n-JFET obtained for channel lengths of 60 nm at a drain current (Iₒₙ) of 140 uA/um. The depth of the silicon containing layer is about 30 nm and about 90 nm for the FDB n-SOI JFET and the PDB SOI n-JFET, respectively. The simulation of the off-current (I_{off}) values were obtained for V_{gs}=0 and V_{ds}=0.5V. The off-state leakage current is plotted on the y-axis 612 in logarithmic scale and the body bias is plotted on the x-axis 610.

Curve 604 depicts the off-state current for a partially-depleted body SOI JFET vs. the body bias at 27 C. Curve 608 depicts the off-state current of a fully-depleted body SOI n-JFET vs. the body bias at 27 C. Curve 604 depicts the off-state current of a partially-depleted body SOI n-JFET vs. the body bias at 27 C. Curve 606 depicts the off-state current of a fully-depleted body SOI n-JFET vs. the body bias at approximately 85 C. Curve 602 depicts the off-state current of a partially-depleted body SOI n-JFET vs. the body bias at approximately 85 C. As can be seen, the fully-depleted body SOI n-JFET has a lower leakage current for both room temperature and elevated temperatures.

In addition, for both partially-depleted and fully-depleted devices, the leakage current is further suppressed with a non-zero body bias. For example, the leakage current is increasingly suppressed with an applied body bias of increased magnitude. Furthermore, the applied body bias effectively reduces off-state leakage current in operating temperatures that span a wide range (e.g., between room temperature and ˜90 C, between 85 C and 125 C, or between 70 C and 150 C).

In general, the off-state current can be reduced by ⅓ to ½ in a fully-depleted body SOI JFET compared to bulk silicon SOI JFET, an SOI JFET, or a partially depleted JFET.

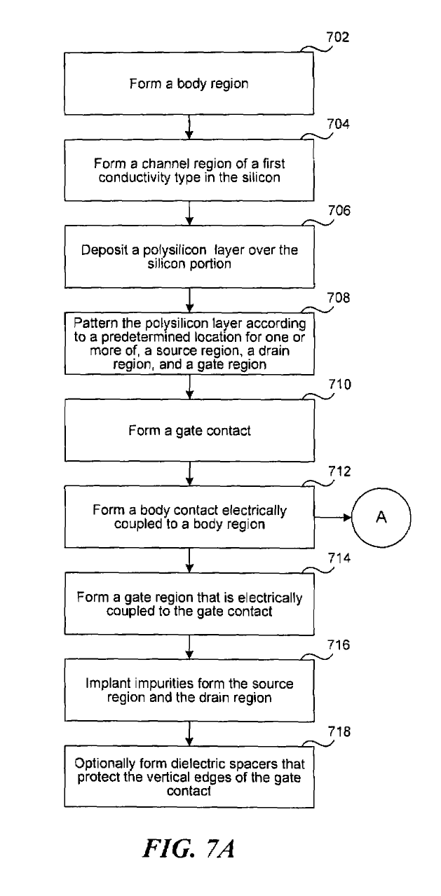

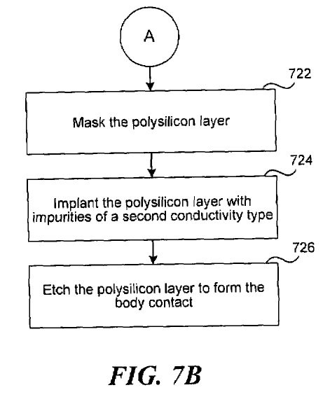

FIG. 7A-FIG. 7B illustrates an example process flow for fabricating an enhancement mode SOI JFET having a fully depleted body region at zero gate bias and zero body bias.

In process 702, a body region is formed in the silicon containing layer of an SOI substrate. The body region can be formed according to any known and/or convenient manner. Generally, an n-type body region is formed for a p-JFET and a p-type body-region is formed for an n-JFET.

In process 704, the channel region is formed. The channel region may be formed according to any known and/or convenient manner, for example, by dopant diffusion in the silicon containing layer of the SOI substrate. For an n-JFET or p-JFET, the channel depth is generally approximately 20-40 nm although other depths may be implemented, without deviating from the novel aspects and features of the embodiments. However, the depth should not be deeper than the depth of the silicon containing portion of the body.

In one non-limiting embodiment, the silicon containing layer is optionally thinned prior to the formation of the body region. The silicon containing layer may be thinned via a suitable etching process or other process known in the art or any suitable or convenient technique. The thickness of the silicon containing layer is selected based on one or more of a channel doping density and a body doping density such that the channel-body depletion region is fully depleted at zero gate bias. For example, the thickness of the silicon containing layer may be approximately within a range of 30-40 nm. In one embodiment, the body doping density is typically although not limited to within the range of 1e¹⁸ to 1e¹⁹ cm⁻³.

For an n-JFET, n-type dopants are used for channel formation. For a p-JFET, p-type dopants are used for channel formation. By way of example but not limitation, in a silicon based device, materials with five valence electrons such as phosphorus and/or arsenic can be used to for n-type doping and materials with three valence electrons such as boron and/or gallium indium can be used for p-type doping. In one embodiment, the channel doping density is typically although not limited to within the range of 5e¹⁸ to 5e¹⁹ cm⁻³. The channel doping density is generally tuned to the thickness of the silicon containing layer such that the gate-channel and channel-body depletion regions are fully depleted at zero bias.

In process 706, polysilicon is deposited on the device. The polysilicon may be doped using any suitable technique, such as diffusion, ion implantation, or in-situ doping. For example, in an n-JFET, the polysilicon may be selectively doped using n-type impurities. When a p-JFET is constructed the polysilicon may be selectively doped using p-type impurities.

In process 708, the polysilicon layer is defined. The polysilicon may be defined via any selective etching process (e.g., plasma etch, chemical etch, dry etch, wet etch, etc.) to form the source, gate, and/or drain contacts. The etching process may involve forming a mask to expose appropriate portions of the polysilicon.

In process 710, the gate contact is formed. The process for gate contact formation masking polysilicon layer according to the location where the gate contact is to be formed. The polysilicon layer can then be implanted with impurities then etched to form the gate contact.

In process 712, a body contact electrically coupled to the body region is formed. The process for body contact formation is described with further reference to the flow chart of the example of FIG. 7B. In process 722, the polysilicon layer is masked according to where the body contact is to be formed. In process 724, the polysilicon layer is implanted with impurities. In process 726, the poly silicon layer is etched to form the body contact.

In process 714, the gate region is formed. The gate region may also be formed according to any known and/or convenient manners, such as dopant diffusion through the polysilicon deposition defining the gate location. For an n-type JFET or p-type JFET, the gate junction depth is generally approximately 10-20 nm although other implantation depths may be implemented. The source/drain/gate length is generally 60 nm each however alternate dimensions may be implemented. In one embodiment, the source/drain/gate region doping density is approximately 1 e²⁰-2e²⁰/cm³.

In process 716, the source and drain regions are formed. The source and drain regions may be formed according to any known and/or convenient manners, for example, by diffusion of dopants through a corresponding polysilicon depositions. For an n-type JFET or a p-type JFET, the source/drain junction formed at Silicon-Buried Oxide Interface is generally approximately 30-40 nm deep although other implantation depths may be implemented, and usually limited to the depth of the silicon containing layer.

In process 718, dielectric sidewall spacers are optionally formed about the polysilicon gate for mitigating high fields between the gate and the channel. For p-JFET or n-JFET devices, each sidewall spacer is generally approximately anywhere between 0-15 nm along the length of the device. The sidewall spacers may include two layers. More particularly, the sidewall spacers include a first layer of silicon dioxide immediately adjacent to the polysilicon followed by a layer of silicon nitride. In one embodiment, the sidewall spacers include a single layer sidewall material of, for example, silicon dioxide.

Having now described various aspects, features, and no-limiting embodiments, attention is now directed to particular non-limiting examples.

In one non-limiting example, there is provided a junction field effect transistor (JFET) including: a silicon containing layer formed on a buried oxide layer; a channel region disposed in the silicon containing layer; a body region disposed between the channel region and the buried oxide layer; a gate region disposed within the channel region forming a gate-channel junction; a body contact electrically coupled to the body region; a depletion region comprising a gate-channel depletion region in the channel region and a channel-body depletion region in the body region; and a thickness of the silicon containing layer is less than or substantially equal to the depletion depth of the depletion region at substantially zero gate region bias and substantially zero body region bias.

In one non-limiting example, in the junction field effect transistor, the gate region is electrically coupled to a gate contact that is operable via an applied gate bias to modulate the depletion depth of the depletion region.

In one non-limiting example, in the junction field effect transistor, the body contact is operable to modulate the depletion depth of the depletion region.

In one non-limiting example, in the junction field effect transistor, the off-state current (I_{off}) is reduced when a non-zero bias is applied to the body contact.

In one non-limiting example, in the junction field effect transistor, the off-state current is reduced by ⅓ to ½ compared to bulk silicon JFET, a SOI JFET, or a partially depleted JFET.

In one non-limiting example, in the junction field effect transistor, the off-state current is reduced in operating conditions with elevated temperatures.

In one non-limiting example, in the junction field effect transistor, the off-state current is reduced for operating conditions between 25-90 degrees Celsius.

In one non-limiting example, in the junction field effect transistor, the off-state current is reduced by a factor of between substantially 8 to 12 times as compared to bulk silicon JFET or SOI JFET.

In one non-limiting example, in the junction field effect transistor, the thickness of the silicon containing layer is chosen as a function of channel doping concentration such that the gate-channel depletion region is substantially fully depleted with zero bias applied to the gate contact and the body contact.

In one non-limiting example, in the junction field effect transistor, the thickness of the silicon containing layer is within the range of 30 to 40 nm and the channel doping concentration is within the range of substantially 5e18 cm⁻³ to 5 e19 cm⁻³.

In one non-limiting example, in the junction field effect transistor, the thickness of the silicon containing layer is chosen as a function of body doping concentration such that the channel-body depletion region is substantially fully depleted with zero bias applied to the gate contact and the body contact.

In one non-limiting example, in the junction field effect transistor, the body doping concentration is substantially within a range of 1e18 cm⁻³ to 1e19 cm⁻³.

In one non-limiting example, in the junction field effect transistor, the gate-channel depletion region is fully depleted when zero bias is applied to the gate contact and the body contact.

In one non-limiting example, in the junction field effect transistor, the channel-body depletion region is fully depleted when zero bias is applied to the gate contact and the body contact.

In one non-limiting example, in the junction field effect transistor, the depletion region is fully depleted throughout the depletion depth when zero bias is applied to the gate contact and the body contact.

In one non-limiting example, in the junction field effect transistor, the thickness of the silicon containing layer does not substantially exceed the combination of the depths of the gate-channel junction, the channel region, and the channel-body depletion region, when zero bias is applied to the gate contact and the body contact.

In one non-limiting example, in the junction field effect transistor, the thickness of the silicon containing layer is substantially 30 nm.

In one non-limiting example, in the junction field effect transistor, the thickness of the silicon containing layer is between 20 nm-50 nm.

In one non-limiting example, in the junction field effect transistor, the junction filed effect transistor further includes: a source region and a drain region formed in the silicon containing layer.

In one non-limiting example, in the junction field effect transistor, the thickness of the buried oxide layer is substantially 150 nm.

In one non-limiting example, in the junction field effect transistor, the gate contact comprises polysilicon or metal.

In one non-limiting example, the junction field effect transistor further includes: polysilicon source and drain contacts electrically coupled to the source region and the drain region, respectively; and the source region and drain region are spaced away from the gate contact by a photo lithographically determined distance.

In one non-limiting example, the junction field effect transistor further includes dielectric material filling the gaps between the source, gate, and drain contacts.

In one non-limiting example, the junction field effect transistor further includes: self-aligned silicide formed on the source, drain, and gate contacts.

In one non-limiting example, the junction field effect transistor further includes a first link region coupling the source region to the channel region and a second link region coupling the drain region to the channel region.

In one non-limiting example, in the junction field effect transistor, the channel, source, and drain regions are of a first conductivity type and the gate region is of a second conductivity type.

In one non-limiting example, in the junction field effect transistor, the silicon containing layer is a silicon layer.

In one non-limiting example, in the junction field effect transistor, the off-state leakage current is reduced.

In one non-limiting example, in the junction field effect transistor, the body bias voltage is a voltage between substantially −Vdd/2 volts and −Vdd volts; wherein Vdd is a value of the positive supply voltage applied to the n-JFET.

In one non-limiting example, in the junction field effect transistor, when the body bias is applied to reduce the off-state leakage current that results from carrier (hole and/or electron) generation and recombination.

In one non-limiting example, in the junction field effect transistor, the body bias depletes thermally generated carriers from the channel to suppress the off-state leakage current.

In one non-limiting example, in the junction field effect transistor, the off-state leakage current saturates with increasing magnitude of body bias.

In one non-limiting example, in the junction field effect transistor, the off-state leakage current is between substantially 100 pA/um and 10 nA/um.

In one non-limiting example, in the junction field effect transistor, the off-state leakage current at higher operating temperatures is reduced relative to the off-state current of the bulk silicon JFET or SOI JFET at the same higher operating temperature.

In one non-limiting example, in the junction field effect transistor, the higher operating temperature is an operating temperature between 70 C and 150 C.

In one non-limiting example, in the junction field effect transistor, the higher operating temperature is an operating temperature between 85 C and 125 C.

In one non-limiting example, in the junction field effect transistor, the capacitance is reduced due to the elimination of a source-drain P-N-junction capacitance.

In one non-limiting example, in the junction field effect transistor, the capacitance at operating biases is reduced as compared to the capacitance of the bulk silicon JFET or SOI JFET by more than 40%.

In one non-limiting example, in the junction field effect transistor, the capacitance is reduced by 30% to 50% of the bulk silicon JFET or SOI JFET.

In one non-limiting example, in the junction field effect transistor, the switching speed is enhanced compared to the switching time of the bulk silicon JFET or SOI JFET.

In one non-limiting example, in the junction field effect transistor the switching time is determined by sub-threshold slope (S-factor).

In one non-limiting example, in the junction field effect transistor, the S-factor is reduced from approximately 80 mV/decade to substantially less than or equal to 70 mV/decade.

In another non-limiting example, there is provided a junction field effect transistor (JFET), including: a silicon containing layer formed on a buried oxide layer; a channel region disposed in the silicon containing layer; a body region disposed between the channel region and the buried oxide layer; a body contact electrically coupled to the body region; and a depletion region comprising a channel-body depletion region in the body region; wherein the channel-body depletion region is substantially fully depleted when zero bias or near-zero bias is applied to the body contact.

In one non-limiting example, the junction field effect transistor further includes: a gate region disposed within the channel region forming a gate-channel junction.

In one non-limiting example, in the junction field effect transistor, the depletion region further includes, a gate-channel depletion region in the channel region; wherein the gate-channel depletion region is fully depleted when zero bias is applied to the body contact.

In one non-limiting example, in the junction field effect transistor, a thickness of the silicon containing layer is less than or substantially equal to a depletion depth of the depletion region when zero bias is applied to the body contact.

In one non-limiting example, in the junction field effect transistor, the gate region is electrically coupled to a gate contact that is operable via an applied gate bias to modulate the depletion depth of the depletion region.

In one non-limiting example, in the junction field effect transistor, the thickness of the silicon containing layer is at most the combination of the depths of the gate-channel junction, the channel region, and the channel-body depletion region.

In one non-limiting example, in the junction field effect transistor, the thickness of the silicon containing layer is chosen as a function of channel doping concentration such that the gate-channel depletion region is fully depleted with zero bias applied to the body contact.

In one non-limiting example, in the junction field effect transistor, the thickness of the silicon containing layer is chosen as a function of body doping concentration such that the channel-body depletion region is fully depleted with zero bias applied to the body contact.

In one non-limiting example, in the junction field effect transistor, the thickness of the silicon containing layer is substantially 30 nm.

In one non-limiting example, in the junction field effect transistor, the thickness of the silicon containing layer is between 20 nm-50 nm.

In one non-limiting example, in the junction field effect transistor, the depletion region is fully depleted throughout the depletion depth with zero bias applied to the body contact.

In one non-limiting example, in junction field effect transistor further includes: a source region and a drain region formed in the silicon containing layer.

In one non-limiting example, in junction field effect transistor further includes: polysilicon source and drain contacts electrically coupled to the source region and the drain region, respectively, wherein the source region and drain region are spaced away from the gate contact by a photo lithographically determined distance.

In one non-limiting example, in the junction field effect transistor, the silicon containing layer is a silicon layer.

In another non-limiting example, there is provided a method of fabricating a junction field-effect transistor (JFET) the method, comprising: forming a body region; forming a channel region of a first conductivity type in a thin silicon portion of a Silicon-On-Insulator (SOI) substrate; depositing a polysilicon layer on the channel region; patterning the polysilicon layer to define one or more of, a source region, a drain region, and a gate region; forming a gate contact; forming a gate region electrically coupled to the gate contact; and forming a body contact electrically coupled to the body region; wherein, a thickness of the thin silicon portion is determined based on one or more of a channel doping density and a body doping density.

In one non-limiting example of the method, the body doping density is substantially within a range of 1e¹⁸ to 1e¹⁹ cm⁻³.

In one non-limiting example of the method, the thickness of the silicon portion is substantially within a range of 30-40 nm.

In one non-limiting example of the method, the method further comprises prior to forming the channel region, thinning a silicon portion of a SOI substrate to the predetermined thickness.

In one non-limiting example of the method, the forming the gate contact, comprises, masking the polysilicon layer; implanting the polysilicon layer with impurities of a second conductivity type; and etching the polysilicon layer to form the gate contact.

In one non-limiting example of the method, the forming the body contact, comprises, heavily doping the polysilicon layer with impurities of the second conductivity type.

In one non-limiting example of the method, the forming the body contact, comprises, masking the polysilicon layer; and etching the polysilicon layer to form the body contact.

In one non-limiting example of the method, the method further comprising, performing a thermal drive-in to diffuse the impurities from the gate contact into the underlying channel region to form the gate region of the second conductivity type.

In one non-limiting example of the method, the channel region and the gate region are formed by ion implantation of impurities of the first conductivity type.

In one non-limiting example of the method, the method further comprising, masking off the gate contact and implanting impurities to form the source region and the drain region.

In one non-limiting example of the method, the method further comprising, forming highly conductive doped link regions of first conductivity type.

In one non-limiting example of the method, the method further comprising: depositing a layer of silicon dioxide over the SOI substrate; depositing a layer of silicon nitride over the SOI substrate; and etching said layer of silicon nitride and the layer of silicon dioxide to form dielectric spacers that protect the vertical edges of the gate contact.

In another non-limiting example, there is provided a method of improving performance of JFET operation, the method, comprising: applying non-zero body bias to a body contact of a JFET to reducing off-state current in a junction field-effect transistor (JFET).

In one non-limiting example of the method, the off-state current in the JFET is reduced for operation in room temperature conditions.

In one non-limiting example of the method, the off-state current in the JFET is reduced for operation in elevated temperature conditions.

In one non-limiting example of the method, the off-state current in the JFET is reduced for operation temperatures between 20-90 degrees Celsius.

In one non-limiting example of the method, the method further comprising: applying a negative body bias to the body contact of an n-type JFET (n-JFET).

In one non-limiting example of the method, the method further comprising: applying a positive body bias to the body contact of a p-type JFET (p-JFET)

In one non-limiting example of the method, the JFET is a partially depleted silicon-on-insulator JFET of the n-type or p-type.

In one non-limiting example of the method, the JFET is a fully depleted silicon-on-insulator JFET of the n-type or p-type.

In another non-limiting example, there is provided a junction field effect transistor of the type having a silicon containing layer formed on a buried oxide layer, a channel region disposed in the silicon containing layer, a body region disposed between the channel region and the buried oxide layer, a body contact electrically coupled to the body region, and wherein a depletion region comprising a gate-channel depletion region in the channel region and a channel-body depletion region in the body region, the junction field effect transistor is characterized in that: a thickness of the silicon containing layer is less than or substantially equal to a depletion depth of the depletion region at substantially zero gate bias and substantially zero body bias.

Unless the context clearly requires otherwise, throughout the description and the claims, the words “comprise,” “comprising,” and the like are to be construed in an inclusive sense, as opposed to an exclusive or exhaustive sense; that is to say in the sense of “including, but not limited to.” As used herein, the terms “connected,” “coupled,” or any variant thereof, means any connection or coupling, either direct or indirect, between two or more elements; the coupling of connection between the elements can be physical, logical, or a combination thereof. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above detailed description of embodiments of the invention is not intended to be exhaustive or to limit the teachings to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed in parallel, or may be performed at different times. Further any specific numbers noted herein are only examples: alternative implementations may employ differing values or ranges.

The teachings of the invention provided herein can be applied to other methods, devices, and/or systems, not necessarily to those described above. The elements and acts of the various embodiments described above can be combined to provide further embodiments.

Any patents and applications and other references noted above, including any that may be listed in accompanying filing papers, are incorporated herein by reference. Aspects of the invention can be modified, if necessary, to employ the systems, functions, and concepts of the various references described above to provide yet further embodiments of the invention.

These and other changes can be made to the invention in light of the above Detailed Description. While the above description describes certain embodiments of the invention, and describes the best mode contemplated, no matter how detailed the above appears in text, the teachings can be practiced in many ways. Details of the device may vary considerably in its implementation details, while still being encompassed by the subject matter disclosed herein. As noted above, particular terminology used when describing certain features or aspects of the invention should not be taken to imply that the terminology is being redefined herein to be restricted to any specific characteristics, features, or aspects of the invention with which that terminology is associated.

In general, the terms used in the following claims should not be construed to limit the invention to the specific embodiments disclosed in the specification, unless the above Detailed Description section explicitly defines such terms. Accordingly, the actual scope of the invention encompasses not only the disclosed embodiments, but also all equivalent ways of practicing or implementing the invention under the claims.

While certain aspects of the invention are presented below in certain claim forms, the inventors contemplate the various aspects of the invention in any number of claim forms. Accordingly, the inventors reserve the right to add additional claims after filing the application to pursue such additional claim forms for other aspects of the invention.

1. A junction field effect transistor (JFET), comprising:
a silicon containing layer formed on a buried oxide layer;
a channel region disposed in the silicon containing layer;
a body region disposed between the channel region and the buried oxide layer;
a gate region disposed within the channel region forming a gate-channel j unction;
a body contact electrically coupled to the body region;
a depletion region comprising a channel-body depletion region in the body region; and
wherein the channel-body depletion region is substantially fully depleted when zero bias or near-zero bias is applied to the body contact.

2. The transistor of claim 1, further comprising:
a gate region disposed within the channel region forming a gate-channel junction; and
the depletion region further comprising a channel-body depletion region in the body region and channel region and a gate-channel depletion region in the channel region; and
a thickness of the silicon containing layer is less than or substantially equal to the depletion depth of the depletion region at substantially zero gate region bias and substantially zero body region bias.

3. The transistor of claim 2, wherein the gate region is electrically coupled to a gate contact that is operable via an applied gate bias to modulate the depletion depth of the depletion region.

4. The transistor of claim 2, wherein the body contact is operable to modulate the depletion depth of the depletion region.

5. The transistor of claim 2, wherein an oil-state current (I_{off}) is reduced when a non-zero bias is applied to the body contact compared to bulk silicon, a SOI JFET, or a partially depleted JFET.

6. The transistor of claim 5, wherein the off-state current is reduced in operating conditions with elevated temperatures.

7. The transistor of claim 2, wherein the body contact is operable to modulate the depletion depth of the depletion region; and the thickness of the silicon containing layer is chosen as a function of channel doping concentration such that the gate-channel depletion region is substantially fully depleted with zero bias applied to the gate contact and the body contact.

8. The transistor of claim 4, wherein the thickness of the silicon containing layer is chosen as a function of body doping concentration such that the channel-body depletion region is substantially fully depleted with zero bias applied to the gate contact and the body contact.

9. The transistor of claim 4, wherein the gate-channel depletion region is fully depleted when zero bias is applied to the gate contact and the body contact.

10. The transistor of claim 4, wherein the channel-body depletion region is fully depleted when zero bias is applied to the gate contact and the body contact.

11. (canceled)

12. The transistor of claim 4, wherein the thickness of the silicon containing layer does not substantially exceed the combination of the depths of the gate-channel junction, the channel region, and the channel-body depiction region when zero bias is applied to the gate contact and the body contact.

13. (canceled)

14. (canceled)

15. The transistor of claim 13, further comprising:
polysilicon source and drain contacts electrically coupled to the source region and the drain region, respectively; and
the source region and drain region are spaced away from the gate contact by a photo-lithographically determined distance.

16. (canceled)

17. The transistor of claim 15, further comprising: self-aligned silicide formed on the source, drain, and gate contacts.

18. The transistor of claim 2, further comprising: a first link region coupling the source region to the channel region and a second link region coupling the drain region to the channel region.

19. (canceled)

20. (canceled)

21. (canceled)

22. (canceled)

23. (canceled)

24. (canceled)

25. (canceled)

26. (canceled)

27. The transistor of clam 1, wherein: a thickness of the silicon containing layer is less than or substantially equal to the depletion depth of the depletion region at substantially zero gate region bias and substantially zero body region bias.

28. (canceled)

29. (canceled)

30. (canceled)

31. (canceled)

32. (canceled)

33. (canceled)

34. (canceled)

35. (canceled)

36. (canceled)

37. The transistor of claim 36, further comprising: polysilicon source and drain contacts electrically coupled to the source region and the drain region, respectively, wherein the source region and drain region are spaced away from the gate contact by a photo-lithographically determined distance.

38. (canceled)

39. A method of fabricating a junction field-effect transistor (JFET) the method, comprising:
forming a body region;
forming a channel region of a first conductivity type in a thin silicon portion of a Silicon-On-Insulator (SOI) substrate;
depositing a polysilicon layer on the channel region;
patterning the polysilicon layer to define one or more of, a source region, a drain region, and a gate region;
forming a gate contact;
forming a gate region electrically coupled to the gate contact; and
forming a body contact electrically coupled to the body region;
wherein, a thickness of the thin silicon portion is determined based on one or more of a channel doping density and a body doping density.

40. The method of claim 39, wherein, the forming the gate contact, comprises,
masking the polysilicon layer;
implanting the polysilicon layer with impurities of a second conductivity type; and
etching the polysilicon layer to form the gate contact.

41. (canceled)

42. The method of claim 39, wherein, the forming the body contact, comprises,
masking the polysilicon layer; and
etching the polysilicon layer to form the body contact.

43. (canceled)

44. (canceled)

45. (canceled)

46. (canceled)

47. The method of claim 39, further comprising:
depositing a layer of silicon dioxide over the SOI substrate;
depositing a layer of silicon nitride over the SOI substrate; and
etching said layer of silicon nitride and the layer of silicon dioxide to form dielectric spacers that protect the vertical edges of the gate contact.

48. A method of improving performance of JFET operation, the method comprising: applying non-zero body bias to a body contact of a JFET to reducing off-state current in a junction field-effect transistor (JFET).

49. (canceled)

50. (canceled)

51. (canceled)

52. (canceled)

53. (canceled)

54. A junction field effect transistor (JFET) of the type having a silicon containing layer formed on a buried oxide layer, a channel region disposed in the silicon containing layer, a body region disposed between the channel region and the buried oxide layer, a body contact electrically coupled to the body region, and wherein a depletion region comprising a gate-channel depletion region in the channel region and a channel-body depletion region in the body region, the junction field effect transistor is characterized in that:
a thickness of the silicon containing layer is less than or substantially equal to a depletion depth of the depletion region at substantially zero gate bias and substantially zero body bias.

55. A junction field effect transistor (JFET), comprising:
a silicon containing layer formed on a buried oxide layer;
a channel region disposed in the silicon containing layer;
a body region disposed between the channel region and the buried oxide layer;
a body contact electrically coupled to the body region; and
a depletion region comprising a channel-body depletion region in the body region.

56. (canceled)

57. (canceled)

58. (canceled)

59. (canceled)

60. (canceled)

61. (canceled)

62. (canceled)

63. A method of making junction field effect transistor (JFET), comprising the steps:
forming a silicon containing layer on a buried oxide layer;
forming a channel region disposed in the silicon containing layer;
forming a body region disposed between the channel region and the buried oxide layer;
forming a body contact electrically coupled to the body region; and
forming a depletion region comprising a channel-body depletion region in the body region.

64. (canceled)

65. (canceled)

66. The transistor of claim 5, further comprising:
a source region and a drain region formed in the silicon containing layer;
polysilicon source and drain contacts electrically coupled to the source region and the drain region, respectively;
the source region and drain region are spaced away from the gate contact by a photo-lithographically determined distance;
dielectric material filling the gaps between the source, gate, and drain contacts; the off-state current is reduced in operating conditions with elevated temperatures;
the depletion region is fully depleted throughout the depletion depth when zero bias is applied to the gate contact and the body contact;
the body bias voltage is a voltage between substantially −Vdd/2 volts and −Vdd volts, wherein Vdd is a value of the positive supply voltage applied to the JFET;
the body bias is applied to reduce the off-state leakage current;
off-state leakage current is reduced and the off-state leakage current saturates with increasing magnitude of body bias; and
the off-state leakage current at higher operating temperatures is reduced relative to the off-state current of the bulk silicon JFET or SOI JFET at the same higher operating temperature;

67. The transistor of claim 1, further comprising:
a gate region disposed within the channel region forming a gate-channel junction; and
a source region and a drain region formed in the silicon containing layer;
the depletion region further comprises a gate-channel depletion region in the channel region, wherein the gate-channel depletion region is fully depleted when zero bias is applied to the body contact;
a thickness of the silicon containing layer is less than or substantially equal to a depletion depth of the depletion region when zero bias is applied to the body contact;
the gate region is electrically coupled to a gate contact that is operable via an applied gate bias to modulate the depletion depth of the depletion region;
the thickness of the silicon containing layer is at most the combination of the depths of the gate-channel junction, the channel region, and the channel-body depletion region:
the thickness of the silicon containing layer is chosen as a function of: channel doping concentration such that the gate-channel depletion region is fully depleted with zero bias applied to the body contact, and body doping concentration such that the channel-body depletion region is fully depleted with zero bias applied to the body contact; and
the depletion region is fully depleted throughout the depletion depth with zero bias applied to the body contact.

68. The method of claim 39, further comprising:
performing a thermal drive in to diffuse the impurities from the gate contact into the underlying channel region to form the gate region of the second conductivity type;
masking off the gate contact and implanting impurities to form the source region and the drain region; and
forming highly conductive doped link regions of first conductivity type;
the forming the body contact, comprises at least one of: (i) heavily doping the polysilicon layer with impurities of the second conductivity type, and (ii) masking the polysilicon layer, and etching the polysilicon layer to form the body contact;
the channel region and the gate region are formed by ion implantation of impurities of the first conductivity type.

69. The method of claim 48, wherein:
the off-state current in the JFET is reduced for operation in at least one of room temperature conditions and elevated temperature conditions; and
further comprising: applying a negative body bias to the body contact of an n-type JFET (n-JFET) and applying a positive body bias to the body contact of a p-type JFET (p-JFET)

70. The transistor of claim 55, further comprising:
a gate region disposed within the channel region forming a gate-channel junction; and
the depletion region further comprising a gate-channel depletion region in the channel region; and
a thickness of the silicon containing layer is less than or substantially equal to the depletion depth of the depletion region at substantially zero gate region bias and substantially zero body region bias.

71. The transistor of claim 55, further comprising:
a gate region disposed within the channel region forming a gate-channel junction;
the depletion region further comprises, a gate-channel depletion region in the channel region; wherein the gate-channel depletion region is fully depleted when zero bias is applied to the body contact;
the channel-body depletion region is substantially fully depleted when zero bias or near-zero bias is applied to the body contact;
the body contact is operable to modulate the depletion depth of the depletion region;
a thickness of the silicon containing layer is less than or substantially equal to a depletion depth of the depletion region when zero bias is applied to the body contact; and
the gate region is electrically coupled to a gate contact that is operable via an applied gate bias to modulate the depletion depth of the depletion region.
